(19) United States
(12) Patent Application Publication
(10) Pub. No.: US 2025/0167001 A1
(43) Pub. Date: May 22, 2025

(54) PATTERNING PROCESSES UTILIZING DIRECTIONAL DEPOSITION

(71) Applicant: Applied Materials, Inc., Santa Clara, CA (US)

(72) Inventors: Tong LIU, San Jose, CA (US); Sony VARGHESE, Manchester, MA (US); Madhur Singh SACHAN, Belmont, CA (US); Keiichi NAKAZAWA, Santa Clara, CA (US); Zhiyu HUANG, Santa Clara, CA (US)

(21) Appl. No.: 18/912,134

(22) Filed: Oct. 10, 2024

Related U.S. Application Data
(60) Provisional application No. 63/623,061, filed on Jan. 19, 2024.
(60) Provisional application No. 63/600,584, filed on Nov. 17, 2023.

(51) Int. Cl. H01L 21/308; H01L 21/311

(52) U.S. Cl. CPC H01L 21/3086; H01L 21/311

(57) ABSTRACT

A method of forming a pattern in a device structure formed on a substrate includes forming one or more patterning layers over a surface of a device structure formed on the substrate, forming patterning features in the one or more patterning layers, depositing a non-conformal film layer over a surface of the one or more patterning layers and the patterning features, and etching a portion of a device feature of the plurality of device features that is exposed within each film layer opening formed within the patterning features. Each of the patterning features are disposed over at least a portion of a device feature of a plurality of device features, and each of the patterning features comprise a feature opening that comprises a first critical dimension (CD) that is greater than the first lateral dimension.

### CROSS-REFERENCE TO RELATED APPLICATIONS

This application claims priority to U.S. Provisional Application Ser. No. 63/600,584 filed Nov. 17, 2023, and Ser. No. 63/623,061 filed Jan. 19, 2024, each of which is herein incorporated by reference in its entirety.

### BACKGROUND

### Field

Embodiments of the invention generally relate to a process of patterning device layers used in semiconductor devices.

### Description of the Related Art

In the manufacture of integrated circuits (IC), shallow-trench-isolation (STI), metal interconnect and related structures are used to form portions of IC devices, such as transistors, inductors, and diodes, that are formed on the surface of a semiconductor substrate. In some back end of the line (BEOL) processes, a dielectric layer is deposited and patterned to form a trench that defines the metal interconnect. One or more metal layers may then be deposited within the trench, and a chemical mechanical polishing (CMP) process may follow to planarize the deposited metal layers. The CMP process also removes excess metal from outside the boundaries of the trench, yielding a metal interconnect confined within the trench of the dielectric layer.

In some front end of the line (FEOL) and BEOL applications, the formed shallow-trench-isolation (STI) and metal interconnect structure are used to form at least a portion of a memory and logic device, such as a DRAM device. Current dynamic random access memory (DRAM) processes include the use of active-cut patterning (D1x, D1y node), cross self-aligned double patterning (X-SADP) or lithography-etch-lithography-etch (LELE) schemes. However, integration of these schemes causes shallow trench isolation (STI) active island area to be reduced as the technology node advances. As integrated circuit dimensions continue to decrease, there is a limit to how far these trenches can be scaled down based on the resolution limitations of the ultraviolet (UV), deep ultraviolet (DUV), and extreme-ultraviolet (EUV) radiation. More specifically, at 22 nanometer (nm) and smaller nodes, current lithography technologies cannot achieve the required dimensions. In one example, conventional EUV scanners are equipped with 0.33 numerical aperture (NA) optics, delivering about a 20 nm resolution. Such a resolution is suitable to print chips on manufacturing technologies featuring metal pitches between 30 nm and 38 nm. However, in a number of applications today, the critical dimensions (CDs) of the patterned features are required to be below 10 nm, and the state-of-the-art solutions to achieve the desired CD level create issues such as having a high complexity, reaching single exposure limits, reached the DUV self-aligned quadruple patterning (SAQP) limit, long processing times and high costs.

Therefore, alternate processes are needed to fabricate features at these sub-resolution dimensions. There is also a need for a solution which reduces cost, processing time, and process variability due to the reduction in patterning steps.

### SUMMARY

Embodiments of the disclosure include a method of forming a pattern in a device structure formed on a substrate, comprising: forming one or more patterning layers over a surface of a device structure formed on the substrate, forming patterning features in the one or more patterning layers, depositing a non-conformal film layer over a surface of the one or more patterning layers and the patterning features, and etching a portion of a device feature of the plurality of device features that is exposed within each film layer opening formed within the patterning features. The device structure comprises a plurality of device features having a first lateral dimension in a first direction, the plurality of device features being spaced apart in the first direction by a first distance, and the first direction is parallel to the surface of the device structure. Each of the patterning features is disposed over at least a portion of a device feature of the plurality of device features, and each of the patterning features comprises a feature opening that comprises a first critical dimension (CD) that is greater than the first lateral dimension. The non-conformal film layer formed within each of the feature openings comprises a first thickness and a second thickness, wherein the first thickness is larger than a second thickness, the second thickness being measured in the first direction and the first thickness being measured in a second direction that is at an angle to the first direction and is parallel to the surface of the device structure, and one or more surfaces of the non-conformal film layer within each of the features openings define a film layer opening.

Embodiments of the disclosure include a method of forming a pattern in a device structure formed on a substrate, comprising: forming one or more patterning layers over a surface of a device structure formed on the substrate, forming patterning features in the one or more patterning layers, directionally depositing a film layer on a surface of the one or more patterning layers and the patterning features, and etching a portion of a device feature of the plurality of device features that is exposed within each film layer opening formed within the patterning features. The device structure comprises a plurality of device features having a first lateral dimension in a first direction, the plurality of device features being spaced apart in the first direction by a first distance, and the first direction is parallel to the surface of the device structure. Each of the patterning features is disposed over at least a portion of a device feature of the plurality of device features, and each of the patterning features comprises a feature opening that comprises a first critical dimension (CD) that is greater than the first lateral dimension. The film layer formed within each of the feature openings comprises a first thickness and a second thickness, wherein the first thickness is larger than a second thickness, the second thickness being measured in the first direction and the first thickness being measured in a second direction that is at an angle to the first direction and is parallel to the surface of the device structure, and one or more surfaces of the film layer within each of the features openings define a film layer opening.

Embodiments of the disclosure may further include a method of forming a pattern in a device structure formed on a substrate. The method may comprise forming one or more patterning layers over a surface of a device structure formed on the substrate, wherein the device structure comprises a plurality of device features having a first dimension in a first direction, the plurality of device features being spaced apart in the first direction by a first distance, the one or more patterning layers comprise a photoresist, and the first direction is parallel to the surface of the device structure. Then forming patterning features in the patterning layer(s), wherein the patterning features comprise a first critical dimension (CD) that is greater than the first dimension; depositing a non-conformal film layer over a surface of the one or more patterning layers and the patterning features, wherein the non-conformal film layer has a first thickness measured in the first direction within the patterning features that is greater than a second thickness of the non-conformal film layer formed within the patterning features, and the second thickness being measured in a second direction, the second direction is at an angle to the first direction and is parallel to the surface of the device structure, a dimension of an opening formed within each of the patterning features, which contain the non-conformal layer, which is measured in the first direction is smaller than the first CD, and a dimension of the opening measured in first direction is less than a dimension of the opening in the second direction. Then etching a portion of a device feature of the plurality of device features that is exposed within the opening formed in the patterning features.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings.

FIG. 1 is a flowchart illustrating a process of forming a patterned device structure, according to one or more embodiments described herein.

FIGS. 2A-2C include cross-sectional views of a partially formed device structure.

FIGS. 3A-3X include cross-sectional views following the series of operations illustrated in FIG. 1 that are used to form of a patterned device structure, according to one or more embodiments.

FIGS. 4A-4B include cross-sectional views of a partially formed device structure following a portion of the series of operations illustrated in FIG. 1.

FIG. 5 is a side view of a directional deposition assembly according to embodiments of the disclosure.

To facilitate understanding, identical reference numerals have been used, where possible, to designate identical elements that are common to the Figures. It is contemplated that elements and features of one embodiment may be beneficially incorporated in other embodiments without further recitation.

### DETAILED DESCRIPTION

Embodiments of the disclosure provide a patterning process sequence that can be used for patterning features having critical dimensions (CDs) below the direct printing capability of a lithographic process. In some applications, the methods disclosed herein can be used to improve the shallow trench isolation patterning using extreme ultraviolet (EUV) lithography and reverse self-aligned double patterning.

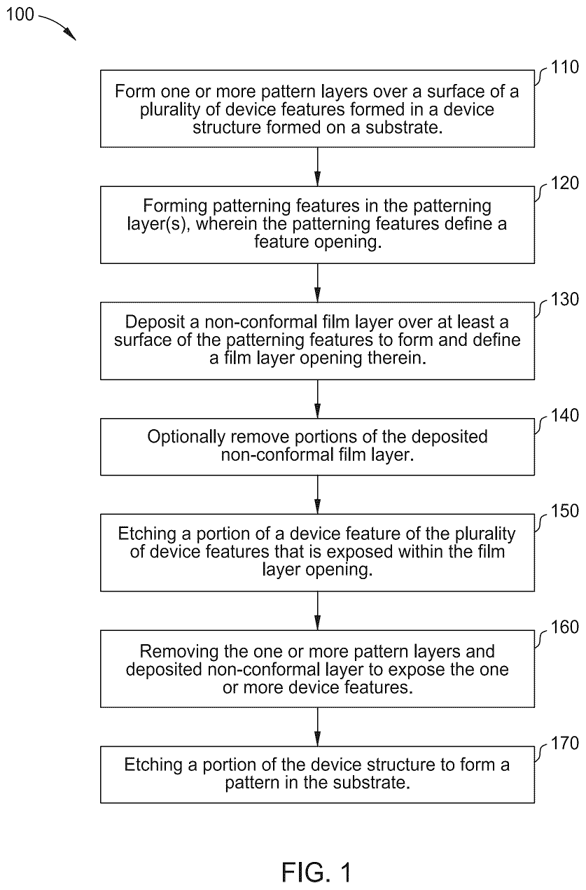

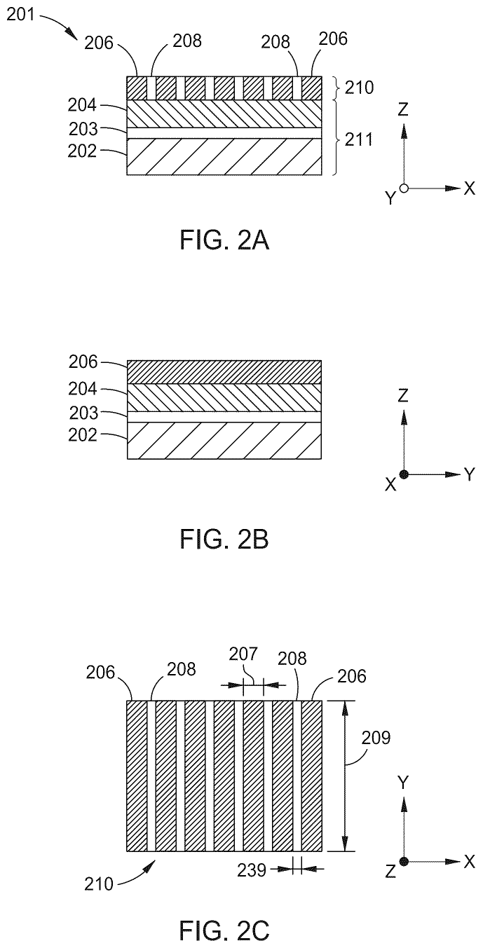

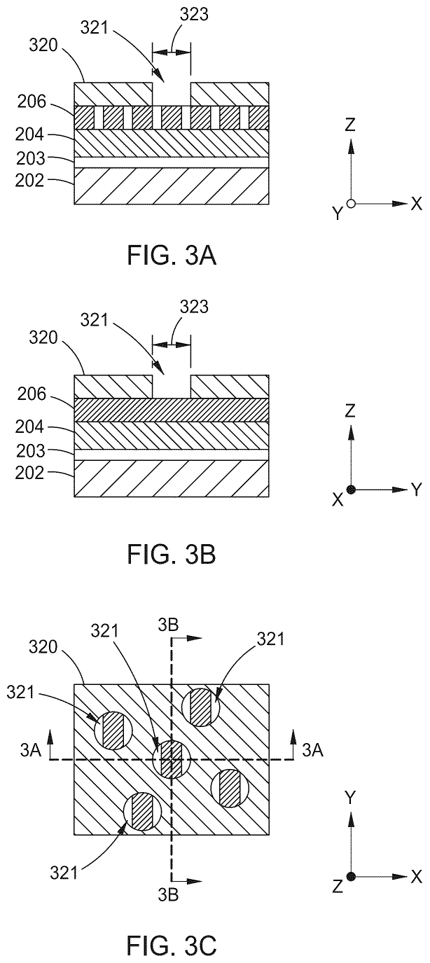

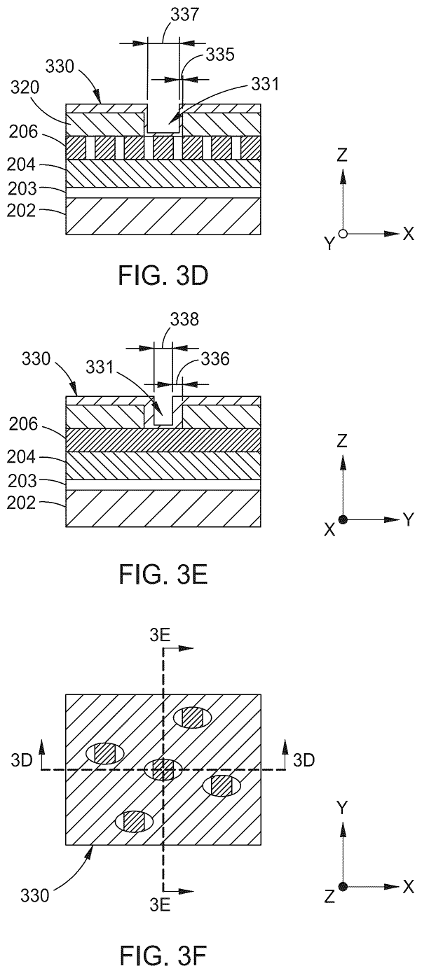

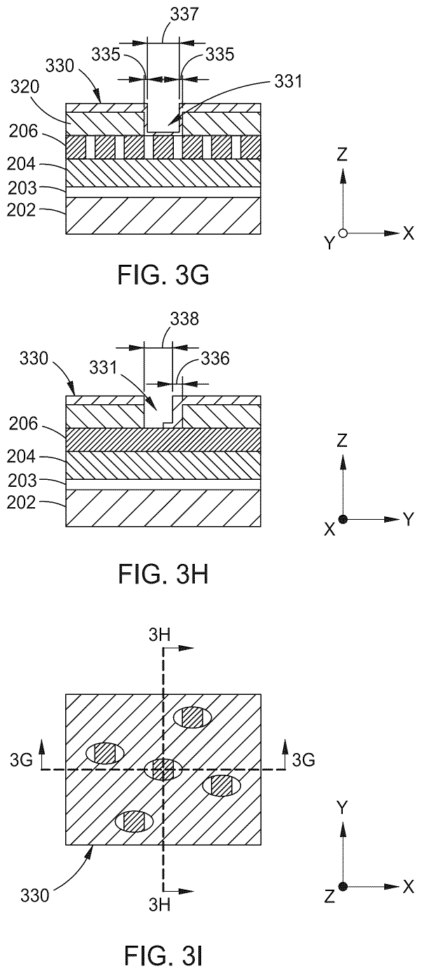

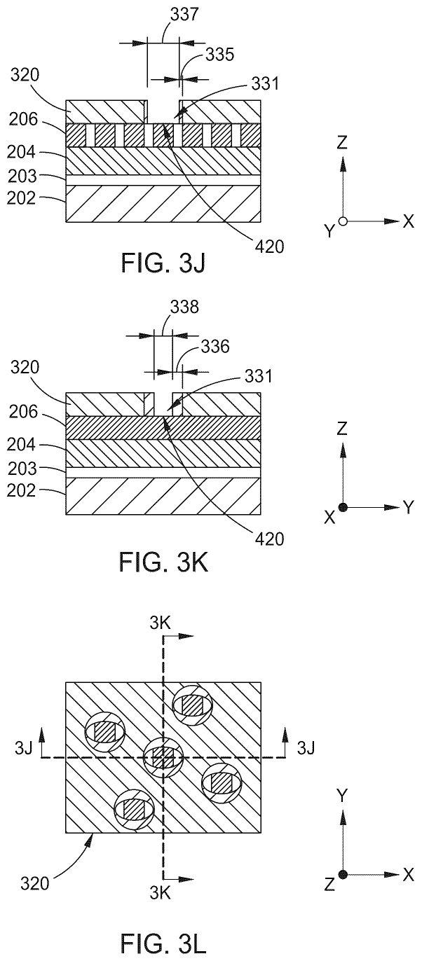

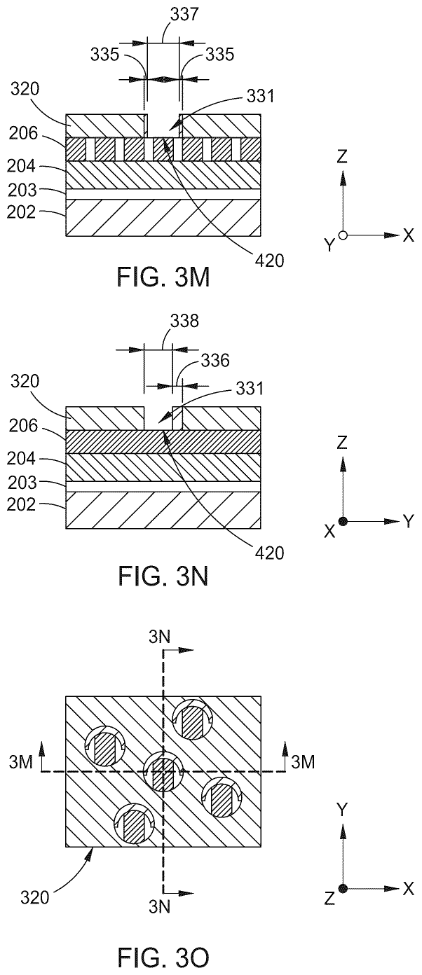

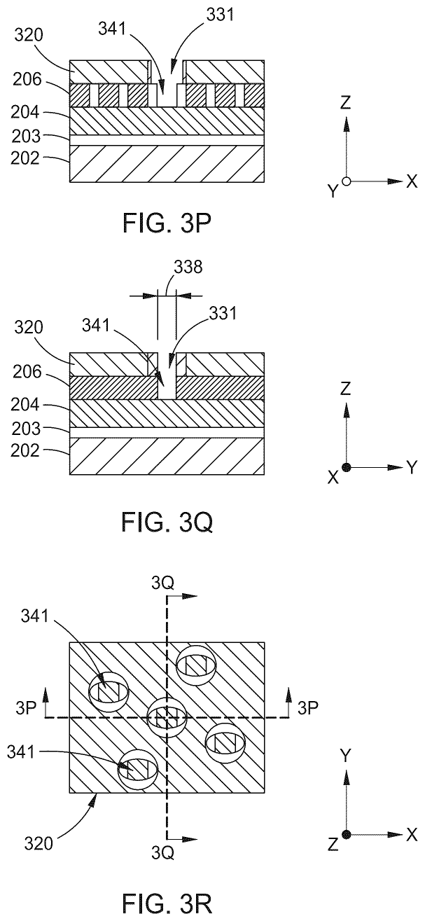

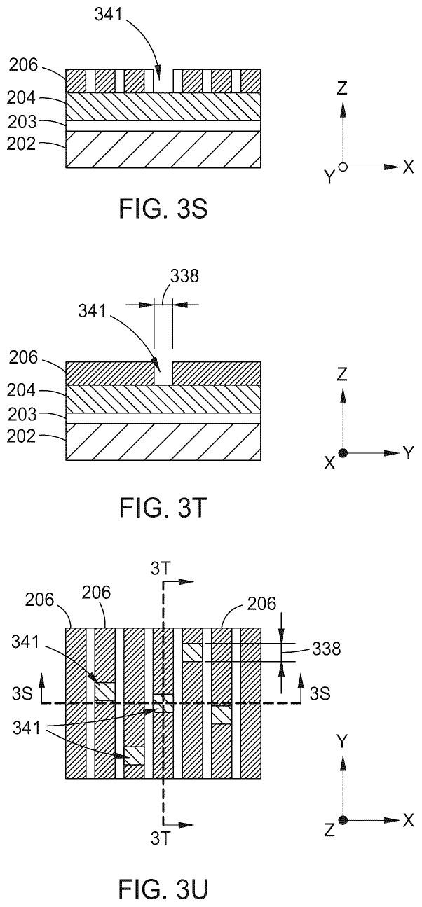

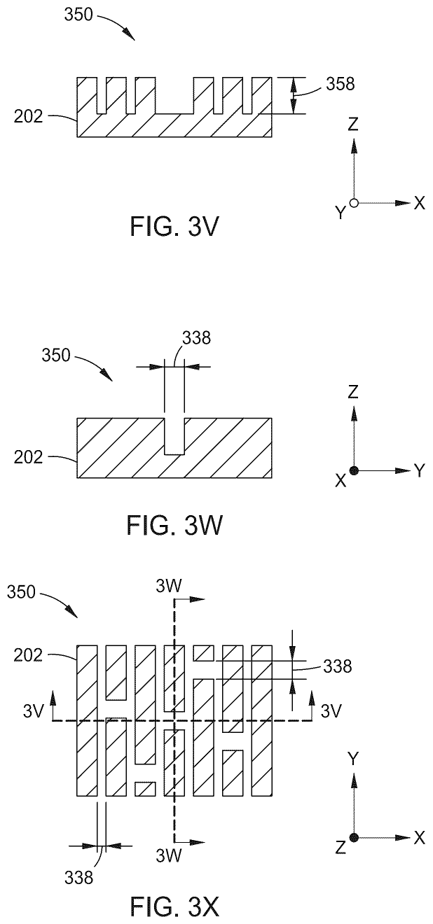

FIG. 1 is a flowchart illustrating a method 100 that is used to pattern a portion of a semiconductor device structure according to one or more embodiments of the disclosure provided herein. FIGS. 2A-2C illustrate cross-sectional views of a partially formed device structure that is used herein to help describe various embodiments of the disclosure provided herein. FIGS. 3A-3X include cross-sectional views following the series of operations illustrated in FIG. 1. The processes described herein are believed to be useful for the formation both logic and memory devices, which can include, but are not limited to, the formation of dynamic random access memory (DRAM) devices (e.g., 6F² DRAM), 3D memory devices (e.g., 3D NAND), backside power delivery network (BSPDN) containing devices, and complementary field-effect transistor (CFET) containing devices. Semiconductor processing systems that contain processing chambers, such as wet and dry processing chambers, can be used to perform the processing steps described herein.

Referring to FIGS. 2A-2C, the method 100 starts with an at least partially formed semiconductor device structure 201 that includes a device patterning layer 210 that is formed over a substrate 211. FIGS. 2A and 2B include side cross-sectional views of the partially formed semiconductor device structure 201, and FIG. 2C is a plan view of the partially formed semiconductor device structure 201. The partially formed semiconductor device structure 201 can be formed by use of various process integration schemes, such as a double patterning lithography (DPL), self-aligned quadruple patterning (SAQP), self-aligned double pattern (SADP), Litho-Etch-Litho-Etch (LELE), or other useful integration process. In one example, as shown in FIGS. 2A-2B, the device patterning layer 210 includes a plurality of device features 206 that are separated by an interlayer dielectric (ILD) 208. In some embodiments, the device features 206 include a metal or a semiconductor material, such as a silicon (Si) containing material (e.g., polysilicon, amorphous silicon, etc.), copper (Cu), molybdenum (Mo), tungsten (W), ruthenium (Ru) or other useful material. In one example, the substrate 211 can include a base substrate 202 that optionally includes one or more layers (e.g., dielectric layers) that are formed thereon. In some embodiments, the substrate 211 includes the base substrate 202, which includes a 100 mm, 150 mm, 200 mm, 300 mm or even a 450 mm crystalline silicon (Si) substrate, and a first layer 203 (e.g., silicon oxide (SiOx)) and a second layer 204 (e.g., silicon nitride (SiNx) layer). The ILD 208 can include a dielectric material such as silicon oxide (SiOx) containing material, a low-k dielectric or other useful material that can be used to provide etch selectivity relative to the device features 206.

In some memory and logic structures today, a spacing 239 is formed between the device features 206 that has a critical dimension (CD) that is less than about 10 nanometers (nm) and a first lateral dimension 207 of the device features 206 are greater than or equal to 10 nm, such as, for example, between about 10 nm and 15 nm, such as 12 nm. In other words, in some embodiments, the semiconductor device structure 201 includes a plurality of device features 206 having a first lateral dimension 207, as measured in a first direction (e.g., X-direction), and the plurality of device features 206 are spaced apart in the first direction by a first distance, or gap, that is filled with the ILD 208. As noted above, conventional EUV scanners are commonly equipped with 0.33 numerical aperture (NA) optics delivers a 20 nm resolution that is suitable for forming structures that have pitches between 30 nm and 38 nm. However, some device fabrication applications seek to subsequently separate portions of each of the device features 206, such as forming a “tip-to-tip” opening 338 (FIGS. 3S-U and 3V-X) in the device features 206, that have a desired critical dimension that is less than the resolution of a single exposure patterning process. The formed opening 338 is configured to segment a device feature 206, which has a second lateral dimension 209 (FIG. 2C) that is greater than the first lateral dimension 207. The desire to form patterned features that have a critical dimension less than the resolution of a single exposure patterning process has required device manufacturers to use much more complex patterning processes to form these smaller features. In some examples, such as in DRAM applications, the desired critical dimension of the opening 338 is less than 10 nm. Therefore, there is a need for a simplified patterning process that is able to form features within a device structure that have a critical dimension (CD) that is smaller than the resolution of lithography tools used during the patterning process.

At operation 110, as illustrated in FIGS. 1 and 3A-3C, a patterning layer 320 is formed on a surface of the partially formed semiconductor device structure 201. FIGS. 3A and 3B include two orthogonally oriented side cross-sectional views of the partially formed semiconductor device structure 201, and FIG. 3C is a plan view of the partially formed semiconductor device structure 201. FIGS. 3A and 3B are formed by use of the sectioning lines 3A-3A and 3B-3B shown in FIG. 3C, respectively. In one embodiment, the patterning layer 320 includes a plurality of layers, such as a carbon hard mask layer (not shown) positioned over the surface of the device patterning layer 210, a dielectric anti-reflective coating (DARC) layer (not shown) positioned over the surface of the carbon hard mask layer, a photoresist (PR) under layer (not shown) positioned over the surface of the DARC layer, and a photoresist layer (not shown) positioned over the surface of the PR under-layer. In some embodiments, the patterning layer 320 includes a EUV photoresist. In some embodiments, the patterning layer 320 includes a carbon containing layer such as a carbon containing hardmask layer (e.g., amorphous carbon layer).

During operation 120, as illustrated in FIGS. 3A-3C, a plurality of patterned openings 321 are formed in a plurality of regions in the patterning layer 320, such as the five regions illustrated in FIG. 3C, by use of various conventional direct photolithography techniques. As illustrated in FIGS. 3A and 3B, each of the patterned openings 321 includes a lateral dimension 323 that has a critical dimension (CD) that is at the limit of a direct print lithographic process or sometimes larger in size. In one example, a EUV scanner is equipped with 0.33 numerical aperture (NA) optics that are configured to form the patterned openings 321 such that they have a lateral dimension 323 that is 20 nm in size by exposing the patterning layer 320 to EUV radiation and then developing the exposed patterning layer 320. In some embodiments, the patterned openings 321 have a circular, square, rectangular, oval or other desired opening shape. While not intending to be limiting to the various aspects of the disclosure provided herein, and for simplicity of discussion reasons, circular shaped patterned openings 321 are primarily disclosed herein. The term “patterned opening” 321 is also referred to herein as a feature opening. In some embodiments, each patterned opening 321 includes a first critical dimension (CD) that is greater than at least one dimension of an underlying feature within the semiconductor device structure 201, such as the first lateral dimension 207 of the device features 206.

As shown in FIG. 3C, the patterned openings 321, due to their inherent CD set by the photolithographic exposure process, are larger than the opening that is desired to be formed in the underlying device features 206, such as forming an opening in an underlying layer using an “active cut” patterning step. In one example, as will be discussed further below, the lateral dimension 323 of each of the circular shaped patterned opening 321 is about 20 nm in size while it is desired to form a “cut” in the exposed region of a device feature 206 that is about 10 nm or less.

At operation 130, as illustrated in FIGS. 3D-3F and FIGS. 3G-31, a non-conformal deposition layer 330 is formed over the surface of the patterning layer 320 and surfaces of the patterned openings 321, which includes the sidewalls of the patterning layer 320. In some cases, the non-conformal deposition layer 330 is also disposed over at least a portion of the exposed semiconductor device structure 201, such as a portion of a device feature 206 and the ILD 208. FIGS. 3D-3F and FIGS. 3G-31 illustrate a non-conformal deposition layer 330 formed over the surface of the patterning layer 320 by use of two different types of directional deposition processes.

FIGS. 3D and 3E include two orthogonally oriented side cross-sectional views of the partially formed semiconductor device structure 201, and FIG. 3F is a plan view of the partially formed semiconductor device structure 201. FIGS. 3D and 3E are formed by use of the sectioning lines 3D-3D and 3E-3E shown in FIG. 3F, respectively. Similarly, FIGS. 3G and 3H include two orthogonally oriented side cross-sectional views of the partially formed semiconductor device structure 201, and FIG. 31 is a plan view of the partially formed semiconductor device structure 201. FIGS. 3G and 3H are formed by use of the sectioning lines 3G-3G and 3H-3H shown in FIG. 31, respectively.

As illustrated in FIGS. 3D-3F, the non-conformal deposition layer 330 has an asymmetric lateral deposition thickness in at least two different lateral directions due to the use of a directional deposition process, which is further described below. In one example, due to the directional nature of the deposition process, the thickness 336 of the non-conformal deposition layer 330 formed on the sidewalls of the patterned openings 321 in the Y-direction is thicker than the thickness 335 of the non-conformal deposition layer 330 formed on the sidewalls in the X-direction. At the end of the deposition process performed during operation 130, the Y-direction opening dimension 338 is reduced to a desired CD dimension (e.g., 10 nm) while the X-direction opening dimension 337 is configured to be larger than Y-direction opening dimension 338 such that any placement error of the patterned openings 321 over the device feature 206 can be accounted for and the subsequent etching process(es) used to remove the portion of the device feature 206 can be assured to physically isolate the remaining portions of the device feature 206 from each other. As shown in FIGS. 3D-3F, the thickness 336 of the non-conformal deposition layer 330 on opposing sides of the patterned openings 321 are both larger than the thickness 335 of the non-conformal deposition layer 330 on opposing sides of the patterned openings 321. The surface of the deposited non-conformal deposition layer 330 within each patterned opening 321 defines a film layer opening 331, which has non-equal opening dimensions (e.g., X-direction opening dimension 337 and Y-direction opening dimension 338), that is then used in one or more subsequent etching processes to define the CD of an etched portion of a material (e.g., portion of the device feature 206) exposed within the film layer opening 331.

As will be discussed further below, the process of forming the non-conformal deposition layer 330 can require two or more extraction assemblies 580 that are configured to directionally deposit the non-conformal deposition layer 330 in two opposing directions (e.g., +Y-direction and −Y-direction in FIG. 3F) to cause the formed thicknesses 336 to be greater than the formed thicknesses 335. In this case, the formed non-conformal deposition layer 330 will be referred to herein as a dual-direction asymmetric non-conformal deposition layer 330.

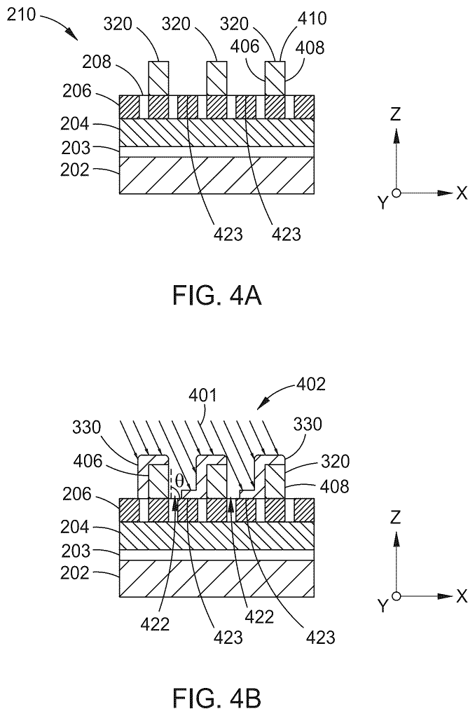

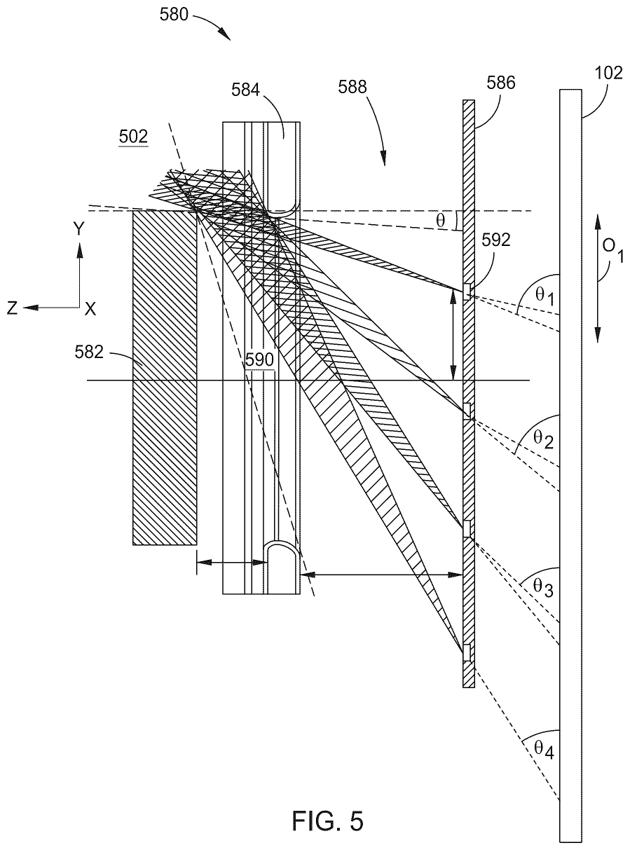

Alternately, as shown in FIGS. 3G-31, a thickness 336 of the non-conformal deposition layer 330 on one side of the patterned openings 321 is larger than the formed thicknesses 335 of the non-conformal deposition layer 330 on opposing sides of the patterned openings 321 in the X-direction. In one example, a process and apparatus for forming the single direction asymmetric non-conformal deposition layer 330 is further described below in relation to FIGS. 4A-4B and 5. In this case, the process of forming the non-conformal deposition layer 330 can require one or more extraction assemblies 580 that are configured to directionally deposit the non-conformal deposition layer 330 in a single direction (e.g., +Y-direction or −Y-direction in FIG. 31) to cause the single sided formed thickness 336 to be greater than the formed thicknesses 335 formed in a second orthogonal direction. In this case, the surface of the deposited non-conformal deposition layer 330 and also a portion of the patterning layer 320, which does not include a portion of the non-conformal deposition layer 330 formed thereon, within each patterned opening 321 defines the film layer opening 331 that is then used in one or more subsequent etching processes to define the CD of an etched portion of a material exposed within the film layer opening 331.

While not intending to limit the scope of the disclosure provided herein, FIGS. 4A-4B and 5 illustrate aspects of a non-conformal deposition layer 330 deposition process and apparatus that can be used during operation 130 to form an asymmetric non-conformal deposition layer 330, such as the non-conformal deposition layer 330 illustrated in FIGS. 3G-31. FIG. 4A depicts a side cross-sectional view of a plurality of patterned openings 321 formed in the patterning layer 320. As shown, each of the plurality of patterned openings 321 includes a first sidewall 406, a second sidewall 408, and an upper surface 410 connecting the first and second sidewalls 406, 408. In some embodiments, the plurality of patterned openings 321 may be formed by a lithography and etch process (e.g., mask etch process), wherein the lithography process has a lower resolution than the desired final structure. Although non-limiting, the plurality of patterned openings 321 may be made from any known hardmask material, e.g., oxide, silicon, carbon, silicon nitride, and the like. In some embodiments, a patterning layer 320 may be formed over exposed surfaces of the patterning layer 320 and exposed portion of the semiconductor device structure 201, including over the first sidewall 406, the second sidewall 408, the upper surface 410 of the patterning layer 320, and over a top surface 423 of the exposed portion of the semiconductor device structure 201.

FIG. 4B depicts a side cross-sectional view of the portion of the semiconductor device structure 201 during formation of a non-conformal deposition layer 330 over the patterning layer 320 and exposed portion of the semiconductor device structure 201. In some embodiments, the non-conformal deposition layer 330 is formed by use of the directional deposition process. More specifically, the directional deposition process is used to deliver a masking material (e.g., oxide, carbon, nitride, silicon (Si), a self-assembled monolayer (SAM), etc.) at a non-zero angle of inclination ϕ relative to a perpendicular direction (e.g., Z-direction) to the top surface 423 of the semiconductor device structure 201. In some embodiments, the non-zero angle of inclination may be selected so that the masking material impacts just the first sidewall 406 and the upper surface 410 of each of the patterned openings 321. In some embodiments, the masking material generally does not form along the top surface 423 of the semiconductor device structure 201 in an area 422 directly adjacent the second sidewall 408 of each of the patterned openings 321. As further shown, the non-conformal deposition layer 330 is prevented from being formed along the second sidewall 408 of each of the patterned openings 321. It will be appreciated that coverage by the masking material is dependent on the non-zero angle of inclination ϕ.

FIG. 5 illustrates a side view of an apparatus for forming the non-conformal deposition layer 330 according to embodiments of the disclosure. As shown, an extraction assembly 580 may be coupled to the plasma chamber 502, and include an extraction plate 584 and a beam blocker 582. The extraction assembly 580 may further include a collimation plate 586, disposed between the extraction plate 584 and the non-conformal deposition layer 330 formed over the patterning layer 320 and exposed portion of the semiconductor device structure 201. Extraction of an ion beam may be achieved by a bias voltage applied between the plasma chamber 502 and non-conformal deposition layer 330, depending upon the targeted ion energy. To generate an angled ion beam, the beam blocker 582 may be arranged to block a portion of the aperture 590, formed with the extraction plate 584, so that an ion beam 588 is extracted from the plasma chamber 502 along the edge of the aperture as shown.

Notably, ions used to form the non-conformal deposition layer 330 may exit the plasma chamber 502 over a range of angles. To select for a given angle of incidence (or narrow range of angles of incidence) (κ), the collimation plate 586 may be provided with a collimation aperture 592 arranged at a specific offset O with respect to an edge of the aperture 590. FIG. 5 illustrates four possible placements for the collimation aperture 592. Increasing the value of O will lead to a higher value of κ. In FIG. 5, for an offset O1, the corresponding q1 is 17-21 degrees. Larger offsets will produce larger angles of incidence. Thus, for a given placement of the collimation aperture 592, ions exiting the plasma chamber 502 will be blocked from traversing to the non-conformal deposition layer 330, except those ions having the suitable angle of incidence to pass through the collimation aperture 592 and strike the portions of the forming non-conformal deposition layer 330. Thus, by switching between different collimation plates having different value of O, the apparatus of FIG. 5 presents a convenient means to vary the angle of incidence of ions of a reactive beam to be applied to a substrate to change the coverage of the non-conformal deposition layer 330 on the patterned openings 321, as generally shown in FIG. 4B.

At operation 140, as illustrated in FIGS. 3J-3L and FIGS. 3M-30, optionally a layer trimming process is performed to remove one or more portions of the deposited non-conformal deposition layer 330 to expose a portion of the top surface 423 of the device patterning layer 210 which is defined by the film layer opening 331. FIGS. 3J-3L and FIGS. 3M-30 each illustrate the remaining portions of the non-conformal deposition layer 330 after performing the trimming process on a dual-direction asymmetric non-conformal deposition layer 330 and a single direction asymmetric non-conformal deposition layer 330, respectively. In some embodiments, the layer trimming process can be performed in the extraction assembly 580, or in a separate plasma processing chamber, by use of plasma dry etching process that is configured to remove the portions of the non-conformal deposition layer 330 by use of a sputtering process. In some embodiments, the trimming process can include a reactive ion etching process that is configured to selectively etch the material used to form the non-conformal deposition layer 330 (e.g., carbon) relative to the materials found in the device features 206 and the ILD 208. As shown in FIGS. 3J-3L and FIGS. 3M-30, the trimming process can include the removal of the non-conformal deposition layer 330 from the top surface 423 of the device patterning layer 210 and also at least a portion of non-conformal deposition layer 330 formed on the top surface of the patterning layer 320. The optional trimming process can also be used to further adjust the X-direction opening dimension 337 and the Y-direction opening dimension 338 as desired by adjusting one or more plasma processing and/or chemical etching process parameters used to remove the portions of the non-conformal deposition layer 330.

At operation 150, as shown in FIGS. 3P-3R, an etching process is performed on the exposed portion of the semiconductor device structure 201 to selectively remove portions the device features 206 that are exposed after performing operations 110-130 and optionally operation 140. While not intending to be limiting as to the scope of the disclosure herein, and for simplicity of discuss purposes, the single direction asymmetric non-conformal deposition layer 330 cross-sectional views have been omitted for the completion of operation 150. FIGS. 3P and 3Q include two orthogonally oriented side cross-sectional views of the partially formed semiconductor device structure 201, and FIG. 3R is a plan view of the partially formed semiconductor device structure 201. FIGS. 3P and 3Q are formed by use of the sectioning lines 3P-3P and 3Q-3Q shown in FIG. 3R, respectively. The etching process performed during operation 150 will include the use of an etchant that will selectively remove the material used to form the device feature 206 versus the material used to form the ILD 208 and stop etching when a portion of the substrate 211 (e.g., second layer 204) is exposed within the opening 341 (FIG. 3R) during the etching process. In other words, the substrate 211 will act as an etch stop during the selective removal of the device feature material. In one example, the second layer 204 of the substrate is a silicon nitride (SiN) containing layer and the etchant used to remove the remaining portions of the device patterning layer 210 includes wet or dry etching chemistries that are configured to selectively etch exposed portion of the metal or silicon containing material of the device feature 206 versus the SiOx of the ILD 208 and the SiNx material of the second layer 204.

At operation 160, as shown in FIGS. 3S-3U, an etching process is performed to remove the remaining portions of the patterning layer 320 and non-conformal deposition layer 330 to expose the top surface 423 of the semiconductor device structure 201. FIGS. 3S and 3T include two orthogonally oriented side cross-sectional views of the partially formed semiconductor device structure 201, and FIG. 3U is a plan view of the partially formed semiconductor device structure 201. FIGS. 3S and 3T are formed by use of the sectioning lines 3S-3S and 3T-3T shown in FIG. 3U, respectively. The etching process performed in operation 160 will include the use of an etchant that will selectively remove the material used to form the patterning layer 320 and non-conformal deposition layer 330. In other words, the remaining materials found on the top surface 423 of the semiconductor device structure 201 act as an etch stop during the selective removal of the patterning layer 320 and non-conformal deposition layer 330. In one example of operation 160, wet and/or dry etching chemistries and processes are used to selectively remove the patterning layer 320 and non-conformal deposition layer 330.

At operation 170, as shown in FIGS. 3V-3X, a series of etching processes are performed to form a patterned substrate 350. FIGS. 3V and 3X include two orthogonally oriented side cross-sectional views of the partially formed semiconductor device structure 201, and FIG. 3X is a plan view of the patterned substrate 350. FIGS. 3V and 3W are formed by use of the sectioning lines 3V-3V and 3W-3W shown in FIG. 3X, respectively. The series of etching processes used to form the patterned substrate 350 include a first etching operation (not shown) that includes the selective removal of the ILD 208 by use of a wet or dry etching process to form openings between the remaining portions of the device features 206. The openings will include the channels formed between adjacent device features 206 and the openings 341 formed between adjacent portions of the device features 206 formed during operation 150.

Next, a second etching operation (not shown) is performed that includes the selective removal of the one or more portions of the substrate 211 that are exposed within the openings formed between the remaining portions of the device features 206, such as the channels formed between adjacent device features and the openings 341 formed between adjacent portions of the device features 206 formed during operation 150. The second etching operation can include the selective removal of the various portions of the substrate 211 versus the material used to form the device features 206 by use of a wet or dry etching process. In some embodiments, the etching process performed during the second etching operation is configured to etch a desired depth 358 within the base substrate 202.

A third etching operation (not shown) that includes the selective removal of the device features 206 and one or more portions of the substrate 211, such that only a portion of the substrate 211 remains, such as the remaining portions of the base substrate 202. The third etching operation can include the removal of the various portions of the device features 206 and substrate 211 by use of a chemical mechanical polishing (CMP) process and/or a wet and/or dry etching process.

The remaining portions of the base substrate 202 are thus used to form the patterned substrate 350. The patterned substrate 350 can then be used in the formation of one or more logic or memory devices.

While the foregoing is directed to embodiments of the present disclosure, other and further embodiments of the disclosure may be devised without departing from the basic scope thereof, and the scope thereof is determined by the claims that follow.

1. A method of forming a pattern in a device structure formed on a substrate, comprising:
forming one or more patterning layers over a surface of a device structure formed on the substrate, wherein
the device structure comprises a plurality of device features having a first lateral dimension in a first direction,
the plurality of device features being spaced apart in the first direction by a first distance, and
the first direction is parallel to the surface of the device structure;
forming patterning features in the one or more patterning layers, wherein
each of the patterning features is disposed over at least a portion of a device feature of the plurality of device features, and
each of the patterning features comprises a feature opening that comprises a first critical dimension (CD) that is greater than the first lateral dimension;
depositing a non-conformal film layer over a surface of the one or more patterning layers and the patterning features, wherein
the non-conformal film layer formed within each of the feature openings comprises a first thickness and a second thickness, wherein the first thickness is larger than a second thickness,
the second thickness being measured in the first direction and the first thickness being measured in a second direction that is at an angle to the first direction and is parallel to the surface of the device structure, and
one or more surfaces of the non-conformal film layer within each of the features openings define a film layer opening; and
etching a portion of a device feature of the plurality of device features that is exposed within each of the film layer openings formed within the patterning features.

2. The method of claim 1, wherein each of the plurality of device features has a second lateral dimension that is measured in the second direction, and the first critical dimension (CD) is less than the second lateral dimension.

3. The method of claim 1, wherein the non-conformal film layer comprises carbon, silicon oxide, silicon nitride, silicon, or a self-assembled monolayer (SAM).

4. The method of claim 3, wherein the one or more patterning layers comprises carbon.

5. The method of claim 1, wherein the one or more patterning layers comprises an extreme ultraviolet (EUV) resist material.

6. The method of claim 1, the device features of the device structure comprise silicon or a metal.

7. The method of claim 6, wherein the substrate comprises a silicon substrate and a dielectric layer that is disposed between the silicon substrate and the device structure.

8. The method of claim 6, wherein a dielectric layer is disposed within the space formed in the first direction between each of the plurality of device features.

9. The method of claim 8, further comprising:
removing the one or more patterning layers from the surface of the device structure;
etching the dielectric layer disposed in the space between each of the plurality of device features of the device structure and a portion of the substrate; and
removing the plurality of device features.

10. A method of forming a pattern in a device structure formed on a substrate, comprising:
forming one or more patterning layers over a surface of a device structure formed on the substrate, wherein
the device structure comprises a plurality of device features having a first lateral dimension in a first direction,
the plurality of device features being spaced apart in the first direction by a first distance, and
the first direction is parallel to the surface of the device structure;
forming patterning features in the one or more patterning layers, wherein
each of the patterning features is disposed over at least a portion of a device feature of the plurality of device features, and
each of the patterning features comprises a feature opening that comprises a first critical dimension (CD) that is greater than the first lateral dimension;
directionally depositing a film layer on a surface of the one or more patterning layers and the patterning features, wherein
the film layer formed within each of the feature openings comprises a first thickness and a second thickness, wherein the first thickness is larger than a second thickness,
the second thickness being measured in the first direction and the first thickness being measured in a second direction that is at an angle to the first direction and is parallel to the surface of the device structure, and
one or more surfaces of the film layer within each of the features openings define a film layer opening; and
etching a portion of a device feature of the plurality of device features that is exposed within each of the film layer openings formed within the patterning features.

11. The method of claim 10, wherein each of the plurality of device features has a second lateral dimension that is measured in the second direction, and the first critical dimension (CD) is less than the second lateral dimension.

12. The method of claim 10, wherein the film layer comprises carbon.

13. The method of claim 12, wherein the one or more patterning layers comprises carbon.

14. The method of claim 10, wherein the one or more patterning layers comprises an extreme ultraviolet (EUV) resist material.

15. The method of claim 10, the device features of the device structure comprise silicon or a metal.

16. The method of claim 15, wherein the substrate comprises a silicon substrate and a dielectric layer that is disposed between the silicon substrate and the device structure.

17. The method of claim 15, wherein a dielectric layer is disposed within the space formed in the first direction between each of the plurality of device features.

18. The method of claim 17, further comprising:
removing the one or more patterning layers from the surface of the device structure;
etching the dielectric layer disposed in the space between each of the plurality of device features of the device structure and a portion of the substrate; and
removing the plurality of device features.

19. A semiconductor device structure, comprising:
a plurality of device features having a first lateral dimension in a first direction that is parallel to a surface of the semiconductor device structure, wherein the plurality of device features is spaced apart in the first direction by a first distance;
a patterning layer over the surface of the semiconductor device structure, wherein the patterning layer comprises a plurality of patterning features, each of which is disposed over at least a portion of a device feature of the plurality of device features and comprises a feature opening that comprises a first critical dimension (CD) that is greater than the first lateral dimension; and
a non-conformal film layer over a surface of the patterning layer and the plurality of patterning features, wherein:
the non-conformal film layer formed within each of the feature openings comprises a first thickness and a second thickness, wherein the first thickness is larger than a second thickness,
the second thickness being measured in the first direction and the first thickness being measured in a second direction that is at an angle to the first direction and is parallel to the surface of the semiconductor device structure,
one or more surfaces of the non-conformal film layer within each of the features openings define a film layer opening, and
a portion of a device feature of the plurality of device features is exposed within each of the film layer openings formed within the patterning features.

20. The semiconductor device structure of claim 19, wherein the non-conformal film layer comprises carbon, silicon oxide, silicon nitride, silicon, or a self-assembled monolayer (SAM).
